(19) United States
(12) Patent Application Publication
(10) Pub. No.: US 2016/0153086 A1
(43) Pub. Date: Jun. 2, 2016

(54) SUBSTRATE PROCESSING APPARATUS

(71) Applicant: JUSUNG ENGINEERING CO., LTD., Gwangju-si (KR)

(72) Inventors: Jae Chan KWAK, Gwangju-si (KR); Byoung Ha CHO, Gwangju-si (KR); Chul-Joo HWANG, Gwangju-si (KR)

(73) Assignee: Jusung Engineering Co., Ltd., Gwangju-si (KR)

(21) Appl. No.: 14/904,402

(22) PCT Filed: Jul. 23, 2014
(86) PCT No.: PCT/KR2014/006691

§ 371 Date: Jan. 11, 2016

(30) Foreign Application Priority Data
Jul. 31, 2013 (KR) 10 2013 0091252

(51) Int. Cl. C23C 16/458; C23C 16/50; C23C 16/455

(52) U.S. Cl. CPC C23C 16/4584; C23C 16/455; C23C 16/50

(57) ABSTRACT

Disclosed is a substrate processing apparatus which is capable of improving uniformity of thin film to be deposited onto a substrate, and also freely adjusting productivity, wherein the substrate processing apparatus may include a process chamber for providing a process space; a substrate supporter, which is rotatably provided in the process space, for supporting at least one substrate; a chamber lid confronting the substrate supporter, the chamber lid for covering an upper side of the process chamber; and a gas distributing part for spatially separating the process space into first and second reaction spaces, and inducing the different kinds of deposition reactions in the respective first and second reaction spaces, wherein the gas distributing part is provided in the chamber lid.

### TECHNICAL FIELD

The present invention relates to a substrate processing apparatus which carries out a process for processing a substrate.

### BACKGROUND ART

Generally, in order to manufacture a solar cell, a semiconductor device and a flat panel display device, it is necessary to form a predetermined thin film layer, a thin film circuit pattern or an optical pattern on a surface of substrate. Thus, a semiconductor manufacturing process may be carried out, for example, a thin film deposition process of depositing a thin film of a predetermined material on a substrate, a photo process of selectively exposing the thin film by the use of photosensitive material, and an etching process of forming a pattern by selectively removing an exposed portion of the thin film.

The thin film deposition process of semiconductor manufacturing process may be carried out in a substrate processing apparatus using chemical vapor deposition (CVD) or atomic layer deposition (ALD) method.

The chemical vapor deposition (CVD) is carried out by distributing process gas for a thin film deposition onto a substrate, and forming a thin film by a chemical vapor reaction. The chemical vapor deposition (CVD) is advantageous in that it can freely adjust productivity owing to a rapid speed of thin film deposition as compared with the atomic layer deposition (ALD). However, the chemical vapor deposition (CVD) has disadvantages such as relatively-low deposition uniformity of thin film and relatively-low quality of thin film as compared with the atomic layer deposition (ALD).

Meanwhile, the atomic layer deposition (ALD) is carried out by sequentially distributing source gas, purge gas, reaction gas and purge gas onto a substrate, and forming a thin film by an atomic layer adsorption reaction. The atomic layer deposition (ALD) is advantageous in that it can realize a uniform thin film. However, the atomic layer deposition (ALD) has a disadvantage of relatively-low thin film deposition speed.

A related art substrate processing apparatus for a thin film deposition is designed to be advantageous to any one of the chemical vapor deposition (CVD) and atomic layer deposition (ALD). Accordingly, if the thin film is deposited onto the substrate by the atomic layer deposition (ALD) in the substrate processing apparatus which is advantageous to the chemical vapor deposition (CVD), the uniformity of thin film is deteriorated. Meanwhile, if the thin film is deposited onto the substrate by the chemical vapor deposition (CVD) in the substrate processing apparatus which is advantageous to the atomic layer deposition (ALD), it has a problem of low productivity to such an extent as to make production impossible.

### DISCLOSURE

### Technical Problem

An aspect of embodiments of the present invention is to provide a substrate processing apparatus which is capable of improving uniformity of thin film to be deposited onto a substrate, and also freely adjusting productivity.

Additional advantages and features of embodiments of the invention will be set forth in part in the description which follows and in part will become apparent to those having ordinary skill in the art upon examination of the following or may be learned from practice of the invention.

### Technical Solution

To achieve these and other advantages and in accordance with the purpose of the invention, as embodied and broadly described herein, there is provided a substrate processing apparatus that may include a process chamber for providing a process space; a substrate supporter, which is rotatably provided in the process space, for supporting at least one substrate; a chamber lid confronting the substrate supporter, the chamber lid for covering an upper side of the process chamber; and a gas distributing part for spatially separating the process space into first and second reaction spaces, and inducing the different kinds of deposition reactions in the respective first and second reaction spaces, wherein the gas distributing part is provided in the chamber lid.

### Advantageous Effect

The substrate processing apparatus according to the present invention includes the following advantages.

Firstly, the process space of the process chamber may be separated into the first and second reaction spaces, and the single-layered or multi-layered thin film may be deposited in each of the first and second reaction spaces through the different deposition reactions, to thereby improve uniformity of the thin film deposited on the substrate, and also to adjust productivity with easiness.

Secondly, the substrate processing apparatus according to the present invention enables to adjust the ratio of the atomic layer adsorption reaction in the first reaction space and the ratio of the chemical vapor reaction in the second reaction space so that it is possible to facilitate improving the quality of thin film and adjusting the productivity.

Thirdly, the substrate processing apparatus according to the present invention enables to deposit the thin film by any one process of the atomic layer adsorption reaction in the first reaction space and the chemical vapor reaction in the second reaction space, and also to dope the thin film with the dopant by the remaining reaction, to thereby perform the various processes for processing the substrate in one process chamber.

### DESCRIPTION OF DRAWINGS

FIG. 1 is an exploded perspective view illustrating a substrate processing apparatus according to the embodiment of the present invention;

FIG. 2 illustrates a gas distributing part shown in FIG. 1;

FIGS. 3 to 6 illustrate modified examples of the gas distributing part shown in FIGS. 1 and 2;

FIG. 7 illustrates a modified example of space separating means in the gas distributing part of the substrate processing apparatus according to the embodiment of the present invention;

FIG. 8 illustrates a modified example of first gas distributing means in the gas distributing part of the substrate processing apparatus according to the embodiment of the present invention;

FIG. 9 illustrates the first embodiment of first gas distributing module shown in FIG. 1;

FIG. 10 illustrates the second embodiment of first gas distributing module shown in FIG. 1;

FIG. 11 illustrates the third embodiment of first gas distributing module shown in FIG. 1.

FIGS. 12 to 15 are rear views illustrating the first gas distributing module, which illustrate various shapes of protruding electrode and electrode inserting portion shown in FIG. 11;

FIGS. 16 to 18 are rear views illustrating the first gas distributing module, which illustrate various shapes of protruding electrode and electrode inserting portion shown in FIGS. 3 to 5;

FIG. 19 illustrates the first embodiment of second gas distributing means shown in FIG. 1; and

FIG. 20 illustrates the second embodiment of second gas distributing means shown in FIG. 1.

### MODE FOR INVENTION

Hereinafter, embodiments of the present invention will be described in detail with reference to the accompanying drawings.

On explanation about the embodiments of the present invention, the following details about the terms should be understood.

The term of a singular expression should be understood to include a multiple expression as well as the singular expression if there is no specific definition in the context. If using the term such as “the first” or “the second”, it is to separate any one element from other elements. Thus, a scope of claims is not limited by these terms.

Also, it should be understood that the term such as “include” or “have” does not preclude existence or possibility of one or more features, numbers, steps, operations, elements, parts or their combinations.

It should be understood that the term “at least one” includes all combinations related with any one item. For example, “at least one among a first element, a second element and a third element” may include all combinations of the two or more elements selected from the first, second and third elements as well as each element of the first, second and third elements.

Also, if it is mentioned that a first element is positioned “on or above” a second structure, it should be understood that the first and second elements may be brought into contact with each other, or a third element may be interposed between the first and second elements.

Hereinafter, a substrate processing apparatus according to the embodiment of the present invention will be described with reference to the accompanying drawings.

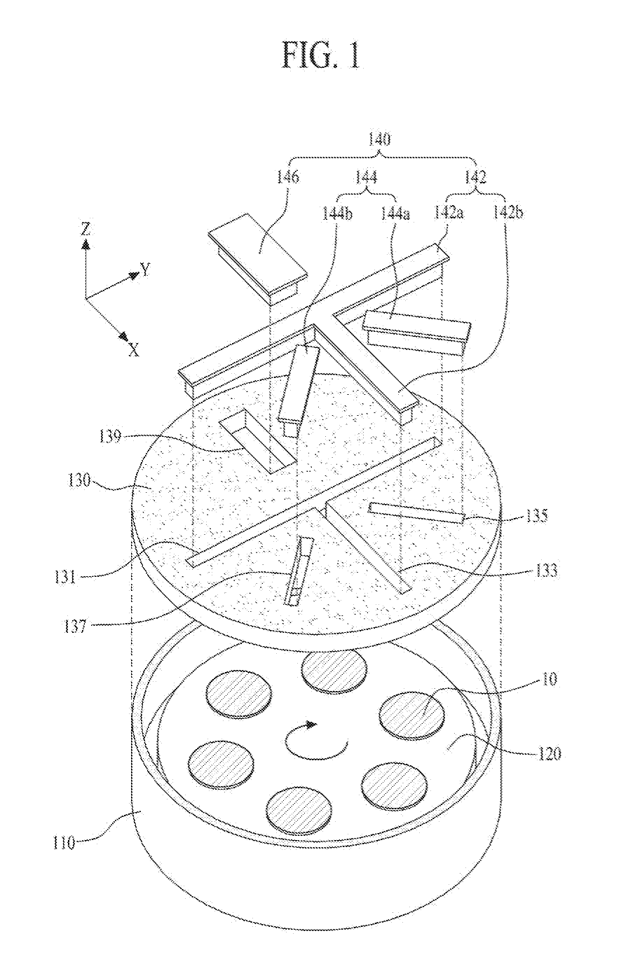

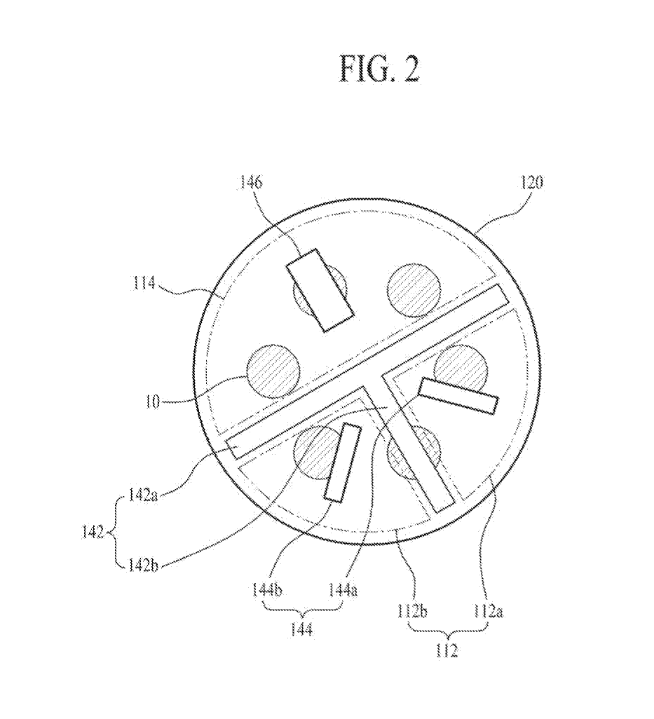

FIG. 1 is an exploded perspective view illustrating a substrate processing apparatus according to the embodiment of the present invention. FIG. 2 illustrates a gas distributing part shown in FIG. 1.

Referring to FIGS. 1 and 2, the substrate processing apparatus according to the embodiment of the present invention may include a process chamber 110, a substrate supporter 120, a chamber lid 130, and a gas distributing part 140. The process chamber 110 provides a process space (reaction space) for substrate processing. The substrate supporter 120 for supporting at least one substrate 10 is rotatably provided inside the process chamber 110. The chamber lid 130 confronting the substrate supporter 120 is provided to cover the chamber lid 130. The gas distributing part 140 is provided in the chamber lid 130 so that the gas distributing part 140 spatially separates the process space of the process chamber 110 into the first and second reaction spaces 112 and 114, and distributes process gases for inducing the different kinds of deposition reactions in the respective first and second reaction spaces 112 and 114.

The process chamber 110 provides the process space for substrate processing. To this end, the process chamber 110 may include a bottom surface, and a chamber sidewall vertically formed on the bottom surface so as to define the process space.

In this case, the bottom surface and/or lateral surface of the process chamber 110 may be communicated with an exhaust port (not shown) for discharging the gas from the reaction space. Also, a substrate inlet (not shown) is provided in at least one sidewall of the process chamber 110. Through the substrate inlet (not shown) of the process chamber 110, the substrate 10 is loaded into or unloaded from the process chamber 110. The substrate inlet (not shown) may include a chamber sealing means (not shown) for sealing the inside of the process space.

The substrate supporter 120 is rotatably provided in the inner bottom of the process chamber 110. The substrate supporter 120 is supported by a rotation axis (not shown) penetrating through a central portion of the bottom surface of the process chamber 110. The substrate supporter 120 may be electrically grounded, may have a predetermined potential (for example, positive potential or negative potential), or may be floating. In this case, the rotation axis exposed out of the bottom surface of the process chamber 110 is sealed by a bellows (not shown) provided in the bottom surface of the process chamber 110.

The substrate supporter 120 supports at least one substrate 10 loaded by an external substrate loading apparatus (not shown). The substrate supporter 120 may be formed in shape of a circular plate. The substrate 10 may be a semiconductor substrate or a wafer. In this case, it is preferable that the plurality of substrates 10 be arranged at fixed intervals in a circular pattern on the substrate supporter 120.

According as the substrate supporter 120 is rotated to a predetermined direction (for example, clockwise direction) by rotation of the rotation axis, the substrate 10 is rotated and thus is moved in accordance with a predetermined order so that the substrate 10 is sequentially exposed to the process gases respectively distributed from the gas distributing part 140 to the first and second reaction spaces 112 and 114. Accordingly, the substrate 10 sequentially passes through the first and second reaction spaces 112 and 114 in accordance with the rotation and rotation speed of the substrate supporter 120, whereby a predetermined thin film is deposited on the substrate 10 by the deposition reaction in at least one reaction space of the first and second reaction spaces 112 and 114.

The chamber lid 130 is provided on the process chamber 110, that is, the chamber lid 130 covers the process chamber 110, to thereby seal the process space. The chamber lid 130 supports the gas distributing part 140 so as to distribute the process gas onto the substrate 10. In this case, a sealing member (not shown) may be provided between the chamber lid 130 and the process chamber 110.

The gas distributing part 140 is detachably provided in the chamber lid 130 so that the gas distributing part 140 spatially separates the process space into the first and second reaction spaces 112 and 114, and distributes the gases for inducting the different deposition reactions in the respective first and second reaction spaces 112 and 114. According to one embodiment of the present invention, the gas distributing part 140 may include a space separating means 142, a first gas distributing means 144, and a second gas distributing means 146.

The space separating means 142 is inserted into the chamber lid 130, whereby the process space of the process chamber 110 is spatially separated into the first and second reaction spaces 112 and 114. Also, the space separating means 142 is provided to spatially separate the first reaction space 112 into first and second gas reaction regions 112a and 112b. To this end, the space separating means 142 may include first and second purge gas distributing frames 142a and 142b to form the gas barriers by downwardly distributing purge gas to the regions locally separated between the substrate supporter 120 and the chamber lid 130. In this case, the purge gas may be non-reaction gas such as nitrogen (N2), argon (Ar), xenon (Ze) or helium (He).

The first purge gas distributing frame 142a is provided to spatially separate the process space of the process chamber 110 into the first and second reaction spaces 112 and 114. That is, the first purge gas distributing frame 142a is formed in a straight line shape whose length is smaller than a diameter of the chamber lid 130. Thus, the first purge gas distributing frame 142a is formed in a central line of the chamber lid 130 with respect to the first-axis direction (Y), whereby the first purge gas distributing frame 142a is inserted into a straight-line shaped first frame inserting part 131. The first purge gas distributing frame 142a is provided with a first purge gas distributing member (not shown) including a plurality of holes or slits for distributing the purge gas supplied from an external purge gas supplier (not shown). The first purge gas distributing frame 142a downwardly distributes the purge gas to the central line of the first-axis direction (Y) of the substrate supporter 120 through the first purge gas distributing member, whereby the gas barrier is formed in the central line of the first-axis direction (Y) of the substrate supporter 120, to thereby spatially separate the process space of the process chamber 110 into the first and second reaction spaces 112 and 114.

The second purge gas distributing frame 142b spatially separates the first reaction space 112 into the first and second gas reaction regions 112a and 112b. That is, the second purge gas distributing frame 142b provided in the straight line shape protrudes from the center of the first purge gas distributing frame 142a toward the edge of the chamber lid 130, wherein a length of the second purge gas distributing frame 142b is smaller than a radius of the chamber lid 130. The second purge gas distributing frame 142b is inserted into a second frame inserting part 133 which is formed in a straight-line shape and provided in a central line of the first frame inserting part 131 with respect to the second-axis direction (X). The second purge gas distributing frame 142b is provided with a second purge gas distributing member (not shown) including a plurality of holes or slits for distributing the purge gas supplied from the external purge gas supplier (not shown). The second purge gas distributing frame 142b downwardly distributes the purge gas to the central line of the second-axis direction (X) inside the first reaction space 112 through the second purge gas distributing member, whereby the gas barrier is formed in the central line of the second-axis direction (X) inside the first reaction space 112, to thereby spatially separate the first reaction space 112 into the first and second gas reaction regions 112a and 112b.

The space separating means 142 is formed to have ‘T’ shape on the plane so that the purge gas is downwardly distributed to the partial region defined in the process space of the process chamber 110. Thus, the plurality of gas barriers are formed between the substrate supporter 120 and the chamber lid 130 so that the process space of the process chamber 110 is spatially separated into the first and second reaction spaces 112 and 114, and the first reaction space 112 is spatially separated into the first and second gas reaction regions 112a and 112b, simultaneously. Eventually, each of the first gas reaction region 112a of the first reaction space 112, the second gas reaction region 112b of the first reaction space 112, and the second reaction space 114 may be spatially separated by the gas barrier formed by the purge gas downwardly distributed and locally provided from the space separating means 142.

The first gas distributing means 144 distributes the process gas for inducing an atomic layer adsorption reaction to the first reaction space 112. In detail, the first gas distributing means 144 distributes the different kinds of gases to the first and second gas reaction regions 112a and 112b spatially separated from each other by the space separating means 142, whereby thin films are deposited by the atomic layer adsorption reaction onto each substrate 10 which sequentially passes through the first gas reaction region 112a, the gas barrier, the second gas reaction region 112b, and the gas barrier by the rotation of the substrate supporter 120. In this case, the thin films formed by the atomic layer adsorption reaction may be a high dielectric film, an insulating film, a metal film, and etc.

The first gas distributing means 144 may include first and second gas distributing modules 144a and 144b.

The first gas distributing module 144a is detachably provided in the chamber lid 130 while being overlapped with the first gas reaction region 112a. In the chamber lid 130 being overlapped with the first gas reaction region 112a, there is a first installing part 135 in which the first gas distributing module 144a is detachably provided.

The first gas distributing module 144a has a first gas distributing space supplied with a first gas from an external first gas supplier (not shown), and the first gas distributing module 144a distributes the first gas, which is supplied to the first gas distributing space, to the first gas reaction region 112a. In this case, the first gas may be a source gas including a main material for the thin film to be deposited on the substrate 10. The first gas may be a source gas including oxide layer, HQ (hydroquinone) oxide layer, High-K thin film, silicon (Si), titanium family element (Ti, Zr, Hf, and etc.), or aluminum (Al) material. For example, the source gas including the silicon (Si) may be Silane(SiH4),Disilane(Si2H6),Trisilane(Si3H8), TEOS(Tetraethylorthosilicate), DCS(Dichlorosilane), HCD(Hexachlorosilane), TriDMAS(Tri-dimethylaminosilane), TSA(Trisilylamine), and etc.

The second gas distributing module 144b is detachably provided in the chamber lid 130 while being overlapped with the second gas reaction region 112b. In the chamber lid 130 being overlapped with the second gas reaction region 112b, there is a second installing part 137 in which the second gas distributing module 144b is detachably provided.

The second gas distributing module 144b has a second gas distributing space supplied with a second gas from an external second gas supplier (not shown), and the second gas distributing module 144b distributes the second gas, which is supplied to the second gas distributing space, to the second gas reaction region 112b. In this case, the second gas may be a gas including some material for the thin film to be deposited on the substrate 10, which reacts with the first gas to form the final thin film, for example, reactive gas such as hydrogen (H2), nitrogen (N2), oxygen (O2), mixture gas of hydrogen (H2) and nitrogen (N2), nitrogen dioxide (NO2), ammonia (NH3), water (H2), or ozone (O3).

The second gas distributing means 146 distributes the process gas for inducing a chemical vapor reaction to the second reaction space 114. In detail, the second gas distributing means 146 distributes third and fourth gases to the second reaction space 114 spatially separated by the space separating means 142. The second gas distributing means 146 is detachably provided in the chamber lid 130 while being overlapped with a central region of the second reaction space 114. In the chamber lid 130 being overlapped with the central region of the second reaction space 114, there is a third installing part 139 in which the second gas distributing means 146 is detachably provided.

The second gas distributing means 146 has third and fourth gas distributing spaces respectively supplied with the third and fourth gases from an external third gas supplier (not shown), and the second gas distributing means 146 distributes the respective third and fourth gases, which are supplied to the third and fourth gas distributing spaces, to the second reaction space 114. Accordingly, a thin film is deposited by the chemical vapor reaction of the third and fourth gases onto each substrate 10 which passes through the second reaction space 114 by the rotation of the substrate supporter 120, or each substrate, which passes through the second reaction space 114 by the rotation of the substrate supporter 120, is doped with a predetermined dopant.

If a material of the thin film formed by the chemical vapor reaction is the same as that of the thin film formed by the atomic layer adsorption reaction, the third gas may be the first gas, and the fourth gas may be the second gas. Meanwhile, if a material of the thin film formed by the chemical vapor reaction is different from that of the thin film formed by the atomic layer adsorption reaction, the source gas of the third gas may be different from the source gas of the first gas, and the reactive gas of the fourth gas may be different from the reactive gas of the second gas. Also, if the substrate 10 is doped with the dopant by the chemical vapor reaction, the third gas may be a dopant gas, and the fourth gas may be the same as or different from the second gas.

A substrate processing method using the substrate processing apparatus according to the embodiment of the present invention will be described in brief as follows.

First, the plurality of substrates 10 are loaded at fixed intervals onto the substrate supporter 120, and are placed thereon.

The plurality of substrates 10 provided below the chamber lid 130 move in the predetermined direction (for example, the clockwise direction) according to the driving of the substrate supporter 120 with the plurality of substrates 10 loaded thereonto. Then, according as the purge gas is downwardly distributed by the use of space separating means 142 of the aforementioned gas distributing part 140, the gas barrier is formed in the predetermined region of the substrate supporter 120, whereby the process space of the process chamber 110 is spatially separated into the first gas reaction region 112a, the second gas reaction region 112b, and the second reaction space 114. After that, the first and second gases are separately distributed to the respective first and second gas reaction regions 112a and 112b through the first gas distributing means 144 of the gas distributing part 140, and the third and fourth gases are distributed to the second reaction space 114 through the second gas distributing means 146 of the gas distributing part 140.

Accordingly, each substrate 10 sequentially passes through the first gas reaction region 112a, the gas barrier region, the second gas reaction region 112b, the gas barrier region, the second reaction space 114 and the gas barrier region by the rotation of the substrate supporter 120. In this case, when each substrate 10 sequentially passes through the first gas reaction region 112a, the gas barrier region, the second gas reaction region 112b and the gas barrier region, the thin film is deposited on the substrate 10 in accordance with the atomic layer adsorption reaction by the first gas, the purge gas, the second gas and the purge gas. When each substrate 10 passes through the second reaction space 114, the thin film is deposited on the substrate 10 in accordance with the chemical vapor reaction by the third and fourth gases.

In the above substrate processing apparatus according to the embodiment of the present invention and the substrate processing method using the same, the gas barrier is formed by the purge gas locally distributed onto the substrate supporter 120, whereby it is possible to simultaneously prepare the first reaction space 112 for the atomic layer adsorption reaction and the second reaction space 114 for the chemical vapor reaction in the process space of the process chamber 110. Accordingly, the atomic layer adsorption reaction and the chemical vapor reaction may be individually controlled in accordance with the quality needed for the thin film to be deposited onto the substrate 10 provided in one process chamber 110, to thereby control the productivity and the quality of thin film at ease.

In the aforementioned description for the gas distributing part, as shown in FIGS. 1 and 2, each of the first and second gas distributing modules 144a and 144b included in the first gas distributing means 144, and the second gas distributing means 146 may be formed in a rectangular shape on the plane, but not limited to this shape. For example, the first and second gas distributing modules 144a and 144b included in the first gas distributing means 144, and the second gas distributing means 146 may be formed in a polygonal shape such as rectangle, trapezoid or fan shape, wherein the respective first gas distributing module 144a, the second gas distributing module 144b and the second gas distributing means 146 may have the same shape or different shapes. That is, according to the present invention, the thin film is deposited on the substrate 10 by the use of gas distributed from the gas distributing part 140 while each of substrate 10 is moved to the below of the gas distributing part 140 by the rotation of the substrate supporter 120. In order to realize the uniform thin film on each substrate 10 in consideration of at least one of a temperature uniformity of the substrate 10 and/or the substrate supporter 120, an angular speed of each substrate by the rotation of the substrate supporter 120 and a gas flow on each substrate 10 by a pumping port (not shown), each of the first gas distributing module 144a, the second gas distributing module 144b and the second gas distributing means 146 may be formed in a rectangular shape on the plane, but not limited to this shape. For example, each of the first gas distributing module 144a, the second gas distributing module 144b, and the second gas distributing means 146 may be formed in a polygonal shape such as rectangle, trapezoid or fan shape, wherein the respective first gas distributing module 144a, the second gas distributing module 144b and the second gas distributing means 146 may have the same shape or different shapes.

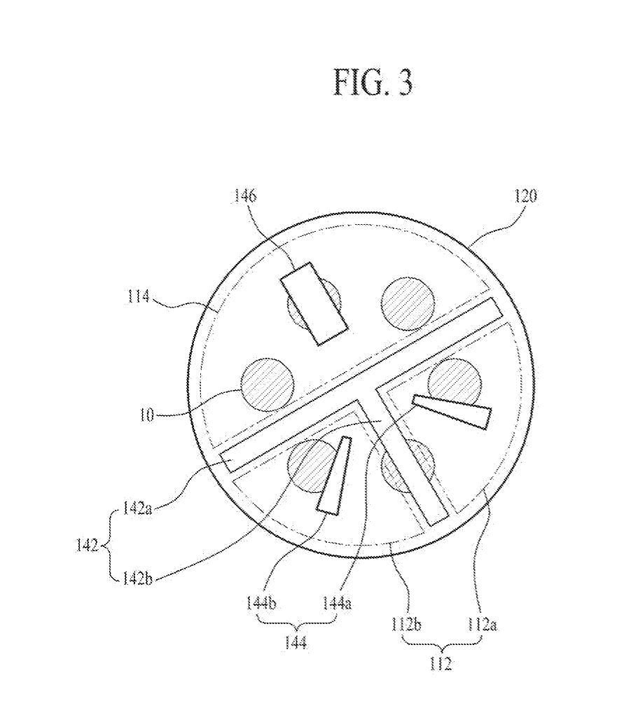

FIGS. 3 to 6 illustrate modified examples of the gas distributing part shown in FIGS. 1 and 2.

First, as shown in FIG. 3, according to the first modified example of the gas distributing part, each of the first and second gas distributing modules 144a and 144b included in the first gas distributing means 144 is formed in a trapezoid shape on the plane, and the second gas distributing means 146 is formed in a rectangular shape on the plane, wherein a size for the second gas distributing means 146 may be larger than a size for each of the first and second gas distributing modules 144a and 144b. In each of the first and second gas distributing modules 144a and 144b formed in the trapezoid shape on the plane, one side being adjacent to the center of the substrate supporter 120 may be relatively shorter than the other side being adjacent to the edge of the substrate supporter 120. A gas distributing amount is gradually increased from one side to the other side in each of the first and second gas distributing modules 144a and 144b.

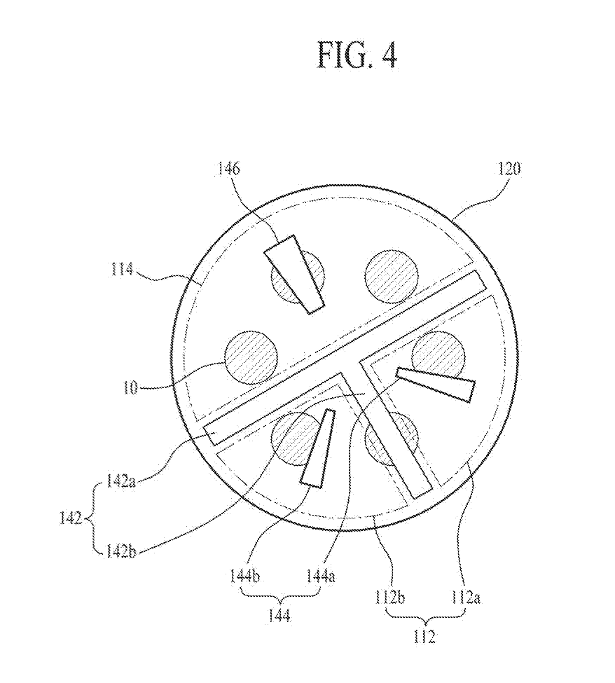

Then, as shown in FIG. 4, according to the second modified example of the gas distributing part, each of the first and second gas distributing modules 144a and 144b included in the first gas distributing means 144, and the second gas distributing means 146 is formed in a trapezoid shape on the plane, wherein one side being adjacent to the center of the substrate supporter 120 may be relatively shorter than the other side being adjacent to the edge of the substrate supporter 120. In this case, a size for the second gas distributing means 146 may be larger than a size for each of the first and second gas distributing modules 144a and 144b. A gas distributing amount is gradually increased from one side to the other side in each of the first gas distributing module 144a, the second gas distributing module 144b and the second gas distributing means 146.

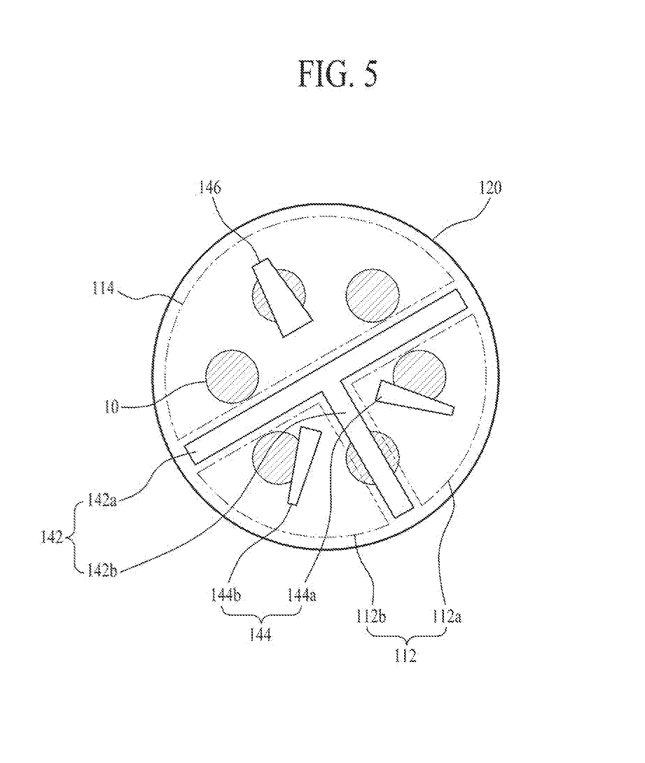

Then, as shown in FIG. 5, according to the third modified example of the gas distributing part, each of the first and second gas distributing modules 144a and 144b included in the first gas distributing means 144, and the second gas distributing means 146 is formed in a trapezoid shape on the plane, wherein one side being adjacent to the center of the substrate supporter 120 may be relatively longer than the other side being adjacent to the edge of the substrate supporter 120. In this case, a size for the second gas distributing means 146 may be larger than a size for each of the first and second gas distributing modules 144a and 144b. A gas distributing amount is gradually decreased from one side to the other side in each of the first gas distributing module 144a, the second gas distributing module 144b and the second gas distributing means 146.

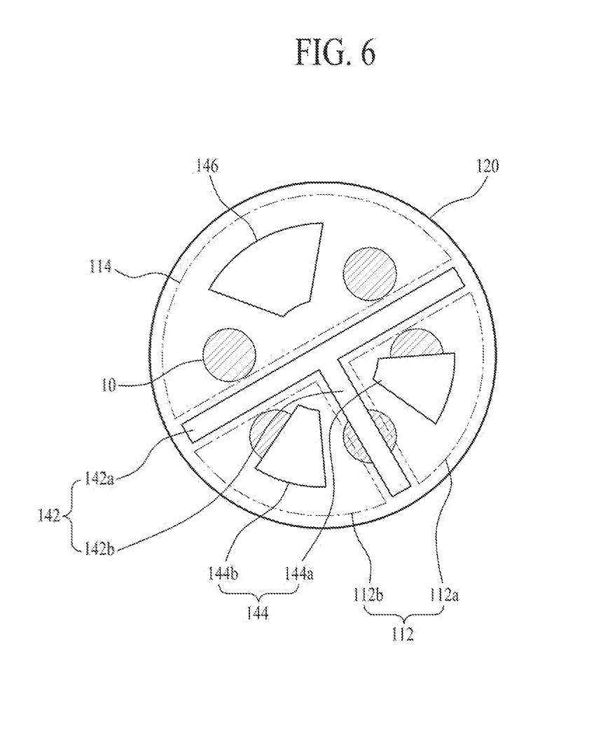

Then, as shown in FIG. 6, according to the fourth modified example of the gas distributing part, each of the first and second gas distributing modules 144a and 144b included in the first gas distributing means 144, and the second gas distributing means 146 is formed in a fan-shape on the plane, wherein one side being adjacent to the center of the substrate supporter 120 may be relatively shorter than the other side being adjacent to the edge of the substrate supporter 120. In this case, a size for the second gas distributing means 146 may be larger than a size for each of the first and second gas distributing modules 144a and 144b. A gas distributing amount is gradually increased from one side to the other side in each of the first gas distributing module 144a, the second gas distributing module 144b and the second gas distributing means 146.

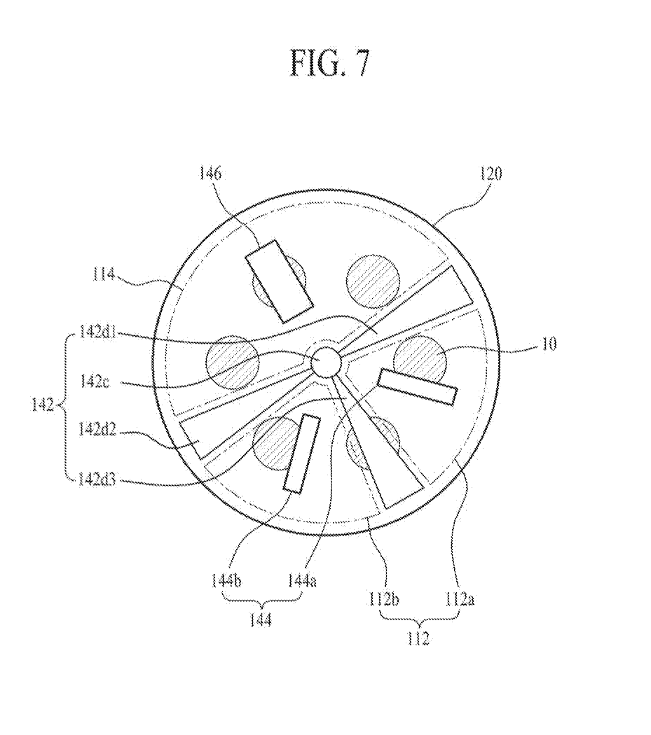

FIG. 7 illustrates a modified example of the space separating means in the gas distributing part of the substrate processing apparatus according to the embodiment of the present invention, wherein the space separating means is changed in its structure. Hereinafter, only the structure of space separating means will be described in detail.

The space separating means 142 may include a central portion 142c, and first to third wings 142d1, 142d2 and 142d3.

The central portion 142c is overlapped with the center of the substrate supporter 120, and the central portion 142c is formed in a circular shape. The central portion 142c is inserted into a central installing part (not shown) formed in the center of the chamber lid 130. The central portion 142c is provided with a plurality of holes or slits for downwardly distributing the purge gas from the external purge gas supplier (not shown) to the center of the substrate supporter 120.

The first and second wings 142d1 and 142d2, which are respectively formed at both sides of the central portion 142c, are respectively inserted into first and second wing installing parts (not shown) formed at both sides of the center of the chamber lid 130. Each of the first and second wings 142d1 and 142d2 is provided with a plurality of holes or slits for downwardly distributing the purge gas from the external purge gas supplier (not shown) to each of the both sides of the center of the substrate supporter 120. Accordingly, the process space of the process chamber 110 is spatially separated into the first and second reaction spaces 112 and 114 owing to the gas barriers formed by the purge gas distributed through the use of central portion 142c and first and second wings 142d1 and 142d2.

The third wing 142d3 is overlapped with the first reaction space 112, and the third wing 142d3 is inserted into a third wing installing part (not shown) formed in the chamber lid 130 to be positioned between the first and second wings 142d1 and 142d2. The third wing 142d3 is provided with a plurality of holes or slits for downwardly distributing the purge gas from the external purge gas supplier (not shown) to the first reaction space 112 between the first and second wings 142d1 and 142d2. Accordingly, the first reaction space 112 is spatially separated into the first and second gas reaction regions 112a and 112b owing to the gas barriers formed by the purge gas distributed through the use of third wing 142d3.

Each of the first, second and third wings 142d1, 142d2 and 142d3 is provided in such a manner that its area is gradually increased from the center of the substrate supporter 120 to the circumference of the substrate supporter 120. In this case, a lateral surface of each of the first to third wings 142d1, 142d2 and 142d3 facing from the center of the substrate supporter 120 toward the circumference of the substrate supporter 120 may be inclined or may be formed in a step shape with a constant slope.

The central portion 142c and the first to third wings 142d1, 142d2 and 142d3 may be formed as one body including the purge gas distributing spaces spatially separated from one another, but not limited to this structure. For example, the process space of the process chamber 110 may be separated into the first and second reaction spaces 112 and 114, and the first reaction space 112 may be formed in various shapes for separation of the first and second gas reaction regions 112a and 112b.

Meanwhile, the central portion 142c of the space separating means 142 distributes the purge gas, but not limited to this structure. For example, the central portion 142c may be used as a central pumping port for pumping the gas staying in the center of the substrate supporter 120 toward the external.

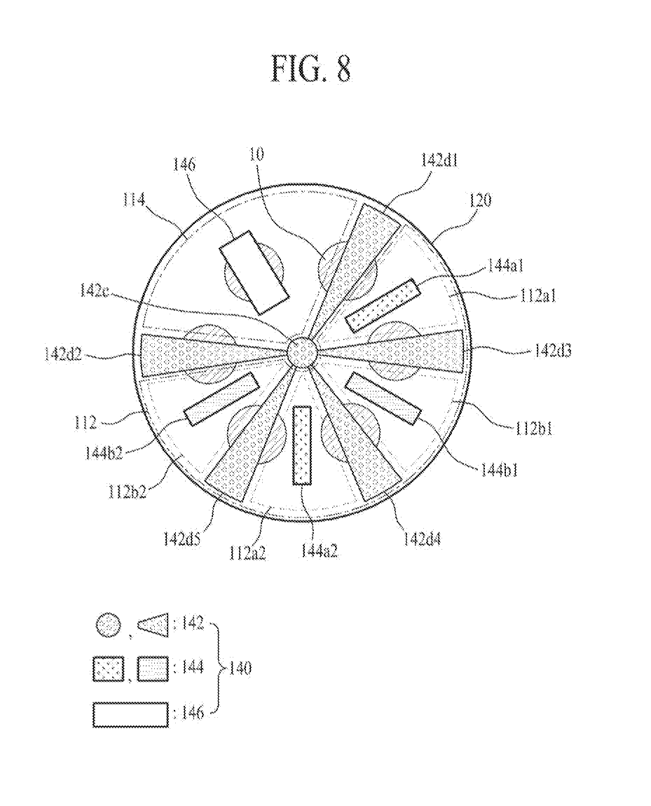

FIG. 8 illustrates a modified example of the first gas distributing means in the gas distributing part of the substrate processing apparatus according to the embodiment of the present invention, wherein the first gas distributing means is changed in its structure. Hereinafter, only the structure of first gas distributing means will be described in detail.

First, the space separating means 142 of the gas distributing part 140 separates the process space of the process chamber 110 into the first and second reaction spaces 112 and 114, and furthermore separates the first reaction space 112 into a plurality of first gas reaction regions 112a1 and 112a2 and a plurality of second gas reaction regions 112b1 and 112b2, wherein the plurality of first gas reaction regions 112a1 and 112a2 alternate with the plurality of second gas reaction regions 112b1 and 112b2. To this end, the space separating means 142 of the gas distributing part 140 may include a central portion 142c, and first to fifth wings 142d1, 142d2, 142d3, 142d4 and 142d5.

As described above, the central portion 142c and the first and second wings 142d1 and 142d2 are provided to separate the process space of the process chamber 110 into the first and second reaction spaces 112 and 114.

The third to fifth wings 142d3, 142d4 and 142d5 are inserted into third to fifth wing installing parts which are provided at fixed intervals in the space between the first and second wing installing parts of the chamber lid 130 so that the third to fifth wings 142d3, 142d4 and 142d4 are provided at fixed intervals in the space between the first and second wings 142d1 and 142d2 while being overlapped with the first reaction space 112.

Each of the third to fifth wings 142d3, 142d4 and 142d5 is provided with a plurality of holes or slits for downwardly distributing the purge gas from the external purge gas supplier (not shown) to a space division region locally defined in the first reaction space 112. Accordingly, the first reaction space 112 of the process chamber 110 is separated into one pair of first gas reaction regions 112a1 and 112a2 and one pair of second gas reaction regions 112b1 and 112b2 which are alternately provided by the plurality of gas barriers formed by the purge gas distributed through the use of third to fifth wings 142d3, 142d4 and 142d5. For example, one pair of first gas reaction regions 112a1 and 112a2 may be respectively prepared between the first and third wings 142d1 and 142d3 and between the fourth and fifth wings 142d4 and 142d5, and one pair of second gas reaction regions 112b1 and 112b2 may be respectively prepared between the third and fourth wings 142d3 and 142d4 and between the second and fifth wings 142d2 and 142d5.

The first gas distributing means 144 may include one pair of first gas distributing modules 144a1 and 144a2 for distributing the first gas to one pair of first gas reaction regions 112a1 and 112a2, and one pair of second gas distributing modules 144b1 and 144b2 for distributing the second gas to one pair of second gas reaction regions 112b1 and 112b2.

Each of the first gas distributing modules 144a1 and 144a2 constituting one pair is detachably provided in the chamber lid 130, and each of the first gas distributing modules 144a1 and 144a2 constituting one pair is overlapped with each of the first gas reaction regions 112a1 and 112a2 constituting one pair. In the chamber lid 130 being overlapped with each of the first gas reaction regions 112a1 and 112a2 constituting one pair, there are one pair of first installing parts (not shown) in which one pair of first gas distributing modules 144a1 and 144a2 are detachably provided. Each of the first gas distributing modules 144a1 and 144a2 constituting one pair has a first gas distributing space supplied with the first gas from an external first gas supplier (not shown), and each of the first gas distributing modules 144a1 and 144a2 constituting one pair distributes the first gas, which is supplied to the first gas distributing space, to each of the first gas reaction regions 112a1 and 112a2 constituting one pair.

Each of the second gas distributing modules 144b1 and 144b2 constituting one pair is detachably provided in the chamber lid 130, and each of the second gas distributing modules 144b1 and 144b2 constituting one pair is overlapped with each of the second gas reaction regions 112b1 and 112b2 constituting one pair. In the chamber lid 130 being overlapped with each of the second gas reaction regions 112b1 and 112b2 constituting one pair, there are one pair of second installing parts (not shown) in which one pair of second gas distributing modules 144b1 and 144b2 are detachably provided. Each of the second gas distributing modules 144b1 and 144b2 constituting one pair has a second gas distributing space supplied with the second gas from an external second gas supplier (not shown), and each of the second gas distributing modules 144b1 and 144b2 constituting one pair distributes the second gas, which is supplied to the second gas distributing space, to each of the second gas reaction regions 112b1 and 112b2 constituting one pair.

The first gas distributing means 144 sequentially distributes the first and second gases to each substrate 10 which moves in accordance with the rotation of the substrate supporter 120. According as each substrate 10 passes through one pair of first gas reaction regions 112a1 and 112a2, one pair of second gas reaction regions 112b1 and 112b2 and the gas barriers in accordance with the rotation of the substrate supporter 120, each substrate 10 is exposed to the first gas, the purge gas, the second gas, the purge gas, the first gas, the purge gas, the second gas and the purge gas in sequence, whereby the thin film is deposited on each substrate 10 in accordance with the atomic layer adsorption reaction.

In FIG. 8, the first gas distributing means 144 includes one pair of first gas distributing modules 144a1 and 144a2 and one pair of second gas distributing modules 144b1 and 144b2, but not limited to this structure. For example, the first gas distributing means 144 may include two or more first and second gas distributing modules which are alternately provided and are spatially separated through the use of three or more gas barriers formed by the purge gas.

In FIGS. 1 to 8, one of the second gas distributing means 146 is provided for distributing the third and fourth gases to the second reaction space 114, but not limited to this structure. In the second reaction space 114, there may be provided with the two or more second gas distributing means 146 at fixed intervals. Furthermore, the gas barrier may be formed in the second reaction space 114 by the aforementioned purge gas. In this case, the two or more second gas distributing means 146 may be spatially separated from one another by the additionally-provided gas barriers.

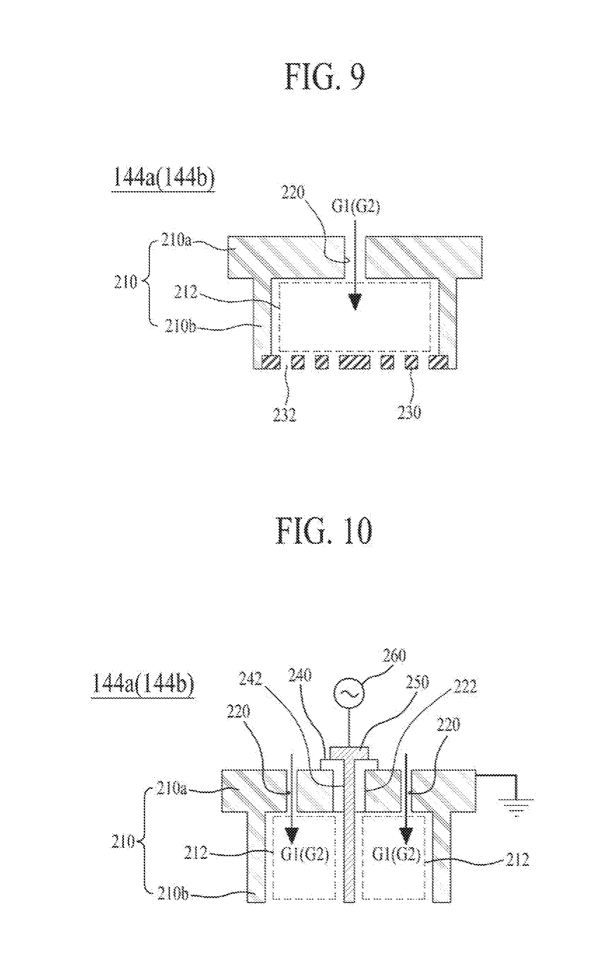

FIG. 9 illustrates the first embodiment of the first gas distributing module shown in FIG. 1.

Referring to FIG. 9 in connection with FIG. 1, the first gas distributing module 144a according to the first embodiment of the present invention may include a housing 210, a gas supply hole 220, and a gas distributing pattern member 230.

The housing 210 is formed in a case shape having a gas distributing space 212 whose lower surface is opened, whereby first gas (G1) supplied to the gas distributing space 212 is distributed downwardly. To this end, the housing 210 may include a plate 210a and a sidewall 210b.

The plate 210a is formed in a flat plate shape, and is combined with an upper surface of the chamber lid 130.

The sidewall 210b protrudes at a predetermined height from a lower edge of the plate 210a so as to provide the gas distributing space 212, wherein the sidewall 210b is inserted into the aforementioned first installing part 135 of the chamber lid 130. In this case, a lower surface of the sidewall 210b may be positioned at the same height as that of the chamber lid 130, may be positioned inside the chamber lid 130, or may be protruding out of the lower surface of the chamber lid 130.

The gas distributing space 212 is surrounded by the sidewall 210b, wherein the gas distributing space 212 is in communication with the first gas reaction region 112a. A length of the gas distributing space 212 is larger than a length of the substrate 10 placed onto the substrate supporter 120.

The gas supply hole 220 vertically penetrating through the plate 210a is in communication with the gas distributing space 212. In this case, the plurality of gas supply holes 220 may be provided at fixed intervals along a length direction of the plate 210a. The gas supply hole 220 is connected with the external first gas supplier through a gas supply pipe (not shown), whereby the first gas (G1) is supplied from the first gas supplier to the gas distributing space 212 through the gas supply hole 220.

The gas distributing pattern member 230 downwardly distributes the first gas (G1) supplied to the aforementioned gas distributing space 212 to the first gas reaction region 112a. In this case, the gas distributing pattern member 230 may be formed as one body with the lower surface of the sidewall 210b so as to cover the lower surface of the gas distributing space 212, or may be formed in an insulating plate (or shower head) of an insulating material with no polarity and combined with the lower surface of the sidewall 210b so as to cover the lower surface of the gas distributing space 212. Accordingly, the gas distributing space 212 is prepared between the plate 210a and the gas distributing pattern member 230, and the first gas (G1) supplied to the gas distributing space 212 through the gas supply hole 220 is diffused and buffered inside the gas distributing space 212 so that the diffused and buffered first gas (G1) is distributed to the first gas reaction region 112a through the gas distributing pattern member 230.

The gas distributing pattern member 230 may include a gas distributing pattern 232 for distributing the first gas (G1) supplied to the gas distributing space 212 toward the substrate 10.

The gas distributing pattern 232 is provided with a plurality of holes (or slits) at fixed intervals so as to penetrate through the gas distributing pattern member 230, whereby the first gas (G1), which is supplied to the gas distributing space 212, is distributed at a predetermined pressure. In this case, a diameter in each of the holes and/or an interval between each of the holes may be determined within a range enabling to uniformly distribute the gas to the entire area of the substrate 10 moving in accordance with the rotation of the substrate supporter 120. For example, the diameter in each of the holes may be gradually increased from the inside of the first gas distributing module 144a being adjacent to the center of the substrate supporter 120 toward the outside of the first gas distributing module 144a being adjacent to the edge of the substrate supporter 120.

Meanwhile, it is possible to omit the gas distributing pattern member 230. In this case, the first gas (G1) is distributed onto the substrate 10 through the gas distributing space 212.

FIG. 10 illustrates the second embodiment of the first gas distributing module shown in FIG. 1.

Referring to FIG. 10, the first gas distributing module 144a according to the second embodiment of the present invention may include a housing 210, a gas supply hole 220, an insulating member 240, and a plasma electrode 250.

First, in case of the first gas distributing module shown in FIG. 9, the first gas (G1) which is not activated is distributed onto the substrate 10. However, it is needed to activate the first gas (G1) and to distribute the activated first gas onto the substrate 10 in accordance with the kind of thin film to be deposited onto the substrate 10. Accordingly, the first gas distributing module 144a according to the second embodiment of the present invention is characterized in that the first gas distributing module 144a is provided with the plasma electrode 250 additionally formed in the gas distributing space 212 of the gas distributing module shown in FIG. 9.

In detail, an insulating member insertion hole 222 being in communication with the gas distributing space 212 is formed in the aforementioned plate 210a of the housing 210. The housing 210 is electrically connected with the chamber lid 130, whereby the aforementioned sidewall 210b of the housing 210, together with the plasma electrode 250, functions as a ground electrode, that is, a first electrode with a first potential for forming plasma.

The insulting member 240 is inserted into the insulating member insertion hole 222. An electrode insertion hole 242 being in communication with the gas distributing space 212 is formed in the insulating member 240, and the plasma electrode 250 is inserted into the electrode insertion hole 242.

The plasma electrode 250 being inserted into the gas distributing space 212 may be arranged in parallel to the sidewall 210b or may be surrounded by the sidewall 210b. In this case, a lower surface of the plasma electrode 250 may be positioned at the same height as the lower surface of the sidewall 210b, or may be protruding out of the lower surface of the sidewall 210b or not.

The plasma electrode 250 functions as a second electrode with a second potential for forming plasma in accordance with a plasma power supplied from a plasma power supplier 260. Accordingly, the plasma is formed between the plasma electrode 250 and the sidewall 210b by a potential difference between the plasma electrode 250 and the sidewall 210b of the housing 210 in accordance with the plasma power, whereby the first gas (G1) supplied to the gas distributing space 212 is activated by the plasma, and is then distributed to the first gas reaction region 112a.

In order to prevent the substrate 10 and/or thin film deposited on the substrate 10 from being damaged by the plasma, an interval (or gap) between the plasma electrode 250 and the sidewall 210b is smaller than an interval between the plasma electrode 250 and the substrate 10. Accordingly, instead of forming the plasma between the substrate 10 and the plasma electrode 250, the plasma is formed between the plasma electrode 250 and the sidewall 210b which are provided at a predetermined interval from the substrate 10 and are arranged in parallel so that it is possible to prevent the substrate 10 and/or the thin film from being damaged by the plasma.

The plasma power may be high frequency (HF) power or radio frequency (RF) power, for example, low frequency (LF) power, middle frequency (MF) power, high frequency (HF) power, or very high frequency (VHF) power. The LF power may have a frequency range of 3 kHz˜300 kHz, the MF power may have a frequency range of 300 kHz˜3 MHz, the HF power may have a frequency range of 3 MHz˜30 MHz, and the VHF power may have a frequency range of 30 MHz˜300 MHz.

An impedance matching circuit (not shown) may be connected with a feeder cable for connecting the plasma electrode 250 and the plasma power supplier 260. The impedance matching circuit matches load impedance and source impedance of the plasma power supplied to the plasma electrode 250 from the plasma power supplier 260. The impedance matching circuit may include at least two of impedance element (not shown) formed of at least one of variable capacitor and variable inductor.

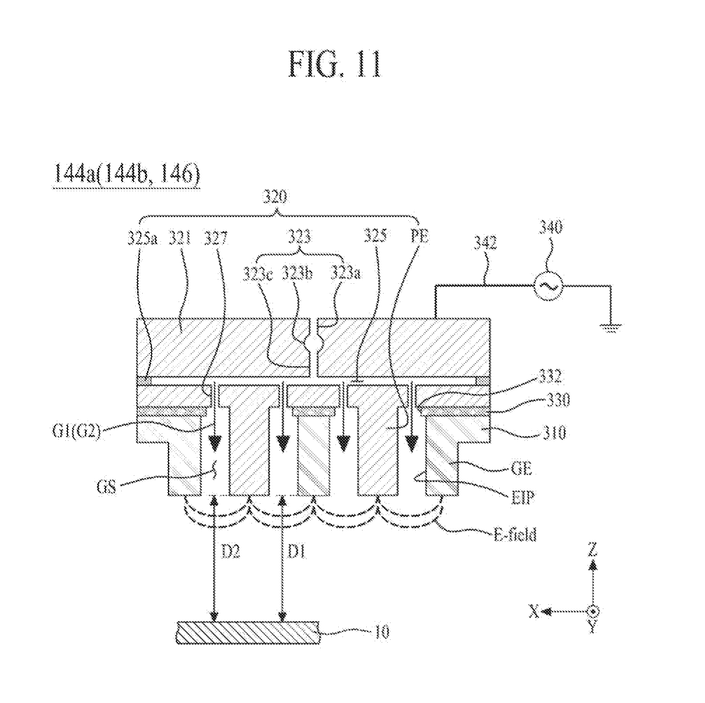

FIG. 11 illustrates the third embodiment of the first gas distributing module shown in FIG. 1.

Referring to FIG. 11, the first gas distributing module 144a according to the third embodiment of the present invention may include a first electrode frame 310, a second electrode frame 320, and an insulating frame 330.

The first electrode frame 310 is inserted into the first installing part 135 which is provided in the chamber lid 130 and is overlapped with the first gas reaction region 112a of the substrate supporter 120, whereby the first electrode frame 310 is electrically grounded, that is, the first electrode frame 310 functions as a first electrode (GE) having a first potential for forming the plasma. The first electrode frame 310 is provided with a plurality of electrode inserting portions (EIP) at fixed intervals. Each of the electrode inserting portions (EIP) penetrates through the first electrode frame 310 in the vertical direction (Z).

The second electrode frame 320 is combined with an upper surface of the first electrode frame 310, wherein the insulating frame 330 is interposed between the first electrode frame 310 and the second electrode frame 320. The second electrode frame 320 functions as a second electrode having a second potential so as to form the plasma, and also the second electrode frame 320 distributes the first gas (G1). To this end, the second electrode frame 320 may include a frame body 321, a plurality of protruding electrodes (PE), a gas supply flow path 323, a plurality of gas distributing flow paths 325, and a plurality of gas distributing holes 327.

The frame body 321 is formed in a flat plate having a predetermined thickness. The frame body 321 is combined with the upper surface of the first electrode frame 310, wherein the insulating frame 330 is interposed between the frame body 321 and the first electrode frame 310. The frame body 321 is electrically connected with a plasma power supplier 340 through a power cable 342, whereby the frame body 321 has the second potential, which is different from the first potential of the first electrode frame 310, by a plasma power supplied from the plasma power supplier 340.

The plasma power supplier 340 supplies the aforementioned plasma power to the frame body 321 through the power cable 342. The power cable 342 may be connected with the aforementioned impedance matching circuit (not shown).

Each of the protruding electrodes (PE) protrudes from a lower surface of the frame body 321 toward the substrate supporter 120, wherein a cross sectional area in each of the protruding electrodes (PE) is smaller than a cross sectional area of the electrode inserting portion (EIP) formed in the first electrode frame 310 so that the protruding electrode (PE) is inserted into the electrode inserting portion (EIP) of the first electrode frame 310 through the insulating frame 330. Accordingly, each lateral surface of the protruding electrode (PE) is provided at a predetermined interval from each lateral surface of the electrode inserting portion (EIP) so that a gap space (GS) is prepared between each lateral surface of the protruding electrode (PE) and each lateral surface of the electrode inserting portion (EIP).

Each of the protruding electrodes (PE) may be formed in a cylinder shape or polygonal pillar whose cross section is the same as a planar shape of the electrode inserting portion (EIP) so that each of the protruding electrodes (PE) may be surrounded by each lateral surface of the electrode inserting portion (EIP). In order to prevent or minimize arcing occurring in a corner for each of the protruding electrodes (PE), each corner of the lateral surface may be concavely or convexly rounded with a predetermined curvature.

The plurality of protruding electrodes (PE) may function as the plasma electrode for forming the plasma, that is, second electrode having the second potential by the plasma power supplied from the plasma power supplier 340 through the frame body 321.

The gas supply flow path 323 is formed inside the frame body 321, wherein the gas supply flow path 323 diverges the first gas (G1) supplied from the first gas supplier to the plurality of gas distributing flow paths 325. In this case, the first gas (G1) may include assist gas for forming the plasma.

The gas supply flow path 323 may include at least one gas supply hole 323a formed at a predetermined depth from an upper surface of the frame body 321 and connected with the first gas supplier through a gas supply pipe (not shown); a gas diverging flow path 323b formed in a first horizontal direction (Y) inside the frame body 321 and be in communication with at least one gas supply hole 323a, wherein the gas diverging flow path 323b diverges the first gas (G1) supplied through the gas supply hole 323a; and a plurality of communication holes 323c for connecting the gas diverging flow path 323b with the plurality of gas distributing flow paths 325. In this case, the gas diverging flow path 323b is formed in a straight line shape to be exposed at both lateral surfaces of the first horizontal direction (Y) among the lateral surfaces of the frame body 321, and both ends of the gas diverging flow path 323b are sealed by welding or sealed by a sealing cap (not shown).

Each of the gas distributing flow paths 325 corresponds to an internal space of the frame body 321 which is supplied with the first gas (G1) diverged by the gas supply flow path 323. The plurality of gas distributing flow paths 325 are formed at fixed intervals inside the frame body 321 along a second horizontal direction (X) being perpendicular to the gas diverging flow path 323b, and are in communication with the gas supply flow path 323, that is, the plurality of communication holes 323c. In this case, each of the gas distributing flow paths 325 is formed in a straight line shape to be exposed at both lateral surfaces of the second horizontal direction (X) among the lateral surfaces of the frame body 321, and both ends of each gas distributing flow path 325 are sealed by welding 325a or sealed by a sealing cap 325a.

Each of the gas distributing holes 327 is formed in a lower surface of the frame body 321, and is in communication with each of the gas distributing flow paths 325 being overlapped with the gas space (GS), whereby each of the gas distributing holes 327 distributes the first gas (G1) supplied from each of the gas distributing flow paths 325 to the gap space (GS). That is, each of the gas distributing holes 327 vertically penetrates through the lower surface of the frame body 321 and each of the gas distributing flow paths 325 being overlapped with the gap space (GS), whereby each of the gas distributing flow paths 325 is in communication with the gap space (GS).

The insulating frame 330 is formed of an insulating material, for example, ceramic material, and the insulating frame 330 is provided between the first and second electrode frames 310 and 320, to electrically insulate the first and second electrode frames 310 and 320 from each other. That is, the insulating frame 330 is detachably provided in a lower surface of the second electrode frame 320 so as to cover the remaining regions except the plurality of protruding electrodes (PE) and the plurality of gas distributing holes 327. A plurality of electrode penetrating portions 332 may be formed in the insulating frame 330, wherein each of the protruding electrodes (PE) of the second electrode frame 320 may be inserted into each of the electrode penetrating portions 332, and then penetrate through each of the electrode penetrating portions 332. A cross sectional shape in each of the electrode penetrating portions 332 is the same as a cross sectional shape in each of the protruding electrode (PE).

A first distance (D1) between a lower surface of the first electrode frame 310 and an upper surface of the substrate 10 may be the same as or different from a second distance (D2) between a lower surface of the protruding electrode (PE) and the upper surface of the substrate 10.

According to one embodiment of the present invention, the first distance (D1) may be the same as the second distance (D2). In this case, the lower surface of the protruding electrode (PE) is positioned at the same horizontal line as that of the lower surface of the first electrode frame 310.

According to another embodiment of the present invention, the first distance (D1) may be different from the second distance (D2). In this case, a length of the protruding electrode (PE) is longer than a total thickness of the insulating frame 330 and the first electrode frame 310 so that the protruding electrode (PE) protrudes out of the lower surface of the first electrode frame 310 in a direction of the upper surface of the substrate 10, or a length of the protruding electrode (PE) is shorter than a total thickness of the insulating frame 330 and the first electrode frame 310 so that the protruding electrode (PE) is not protruding out of the lower surface of the first electrode frame 310 in a direction of the upper surface of the substrate 10.

The aforementioned first electrode frame 310, the insulating frame 330 and the second electrode frame 320 may be formed as one module, and be detachably combined with the first installing part 135 of the chamber lid 130.

The first gas distributing module 144a according to the third embodiment of the present invention forms the plasma from the first gas (G1) distributed to the gap space (GS) inside the gap space (GS) or below the gap space (GS) by the use of electric field (E-field) according to a potential difference between the first electrode frame 310 and the plurality of protruding electrodes (PE), and then distributes the first gas (G1) activated by the plasma to the first gas reaction region 112a. In this case, the plasma may be formed inside the gap space (GS) or below the gap space (GS) according to the protruding length of the protruding electrode (PE).

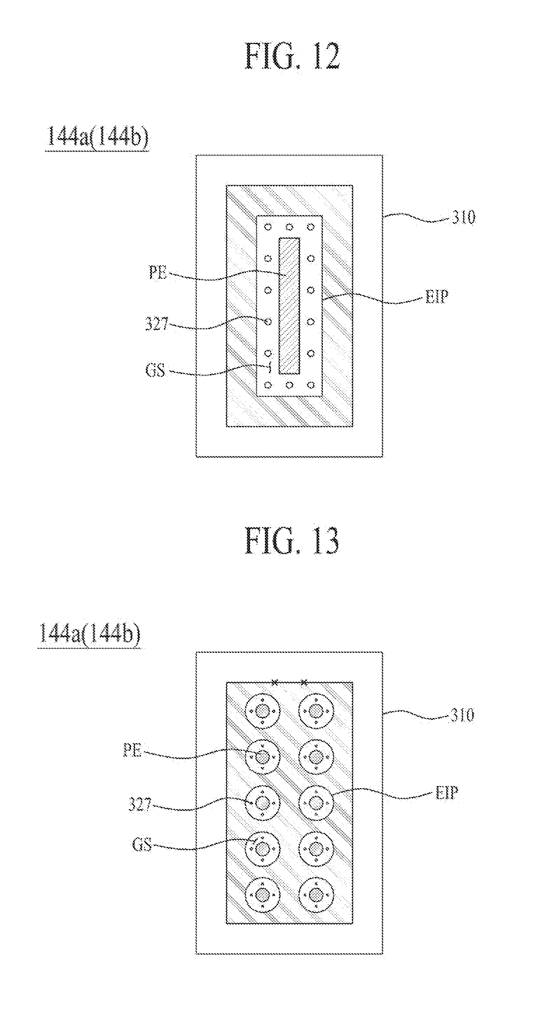

FIGS. 12 to 15 are rear views illustrating the first gas distributing module shown in FIG. 11, which illustrate various shapes of the protruding electrode and the electrode inserting portion shown in FIG. 11. Accordingly, only the various shapes of the protruding electrode and the electrode inserting portion will be described in detail as follows.

First, as shown in FIG. 12, the first gas distributing module 144a may include one electrode inserting portion (EIP) and one protruding electrode (PE).

The electrode inserting portion (EIP) according to one modified embodiment of the present invention is formed in a rectangular shape on the plane. The protruding electrode (PE) according to one modified embodiment of the present invention is formed in a rectangular pillar which is provided at a predetermined interval from the lateral surface of the electrode inserting portion (EIP) and is also surrounded by the lateral surface of the electrode inserting portion (EIP). The aforementioned gap space (GS) is prepared between the lateral surface of the electrode inserting portion (EIP) and the protruding electrode (PE), and the first gas is distributed from the plurality of gas distributing holes 327 of the second electrode frame 320 to the gap space (GS).

Then, as shown in FIG. 13, the first gas distributing module 144a may include the plurality of electrode inserting portions (EIP) and the plurality of protruding electrodes (PE).

The electrode inserting portion (EIP) according to another modified embodiment of the present invention is formed in a circular shape on the plane and may be arranged in a lattice configuration. The protruding electrode (PE) according to another modified embodiment of the present invention is formed in a circular pillar which is provided at a predetermined interval from the lateral surface of the electrode inserting portion (EIP) and is also surrounded by the lateral surface of the electrode inserting portion (EIP). The aforementioned gap space (GS) is prepared between the lateral surface of the electrode inserting portion (EIP) and the protruding electrode (PE), and the first gas is distributed from the plurality of gas distributing holes 327 of the second electrode frame 320 to the gap space (GS).

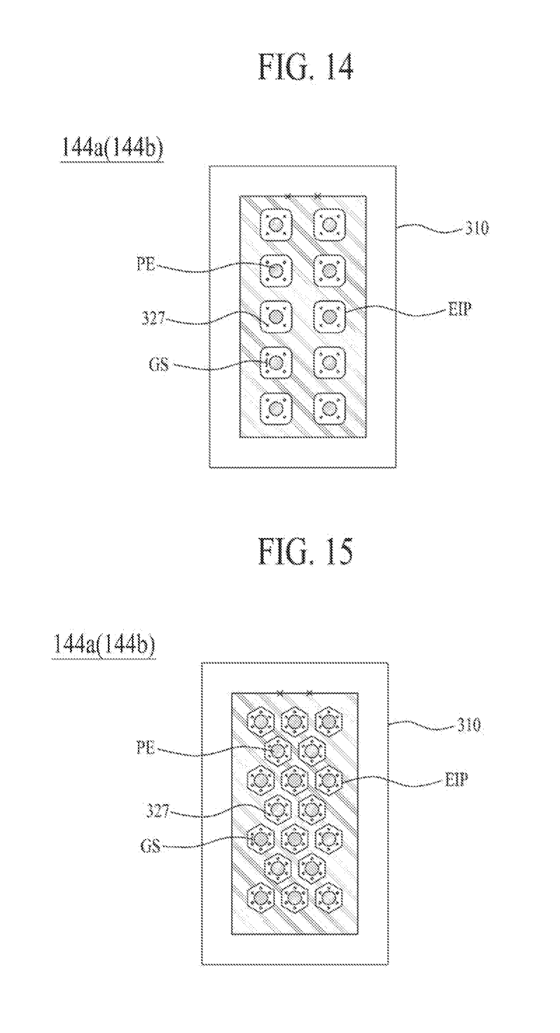

As shown in FIG. 14, the electrode inserting portion (EIP) according to another modified embodiment of the present invention may be formed in a square shape (or rectangular shape) on the plane or a square shape (or rectangular shape) whose each corner is rounded, and may be arranged in a lattice configuration. As shown in FIG. 15, the electrode inserting portion (EIP) according to another embodiment of the present invention may be formed in a polygonal shape whose internal angle is above 90° on the plane, and may be arranged in a honeycomb shape.

As shown in FIG. 14 or 15, the protruding electrode (PE) according to another modified embodiment of the present invention may be formed in a cylinder shape which is provided at a predetermined interval from the lateral surface of the electrode inserting portion (EIP) and is also surrounded by the lateral surface of the electrode inserting portion (EIP), but not limited to this shape. The protruding electrode (PE) according to another modified embodiment of the present invention may be formed in a pillar shape which is the same as that of the electrode inserting portion (EIP), or may be formed in a pillar shape having a polygonal cross section whose internal angle is above 90°.

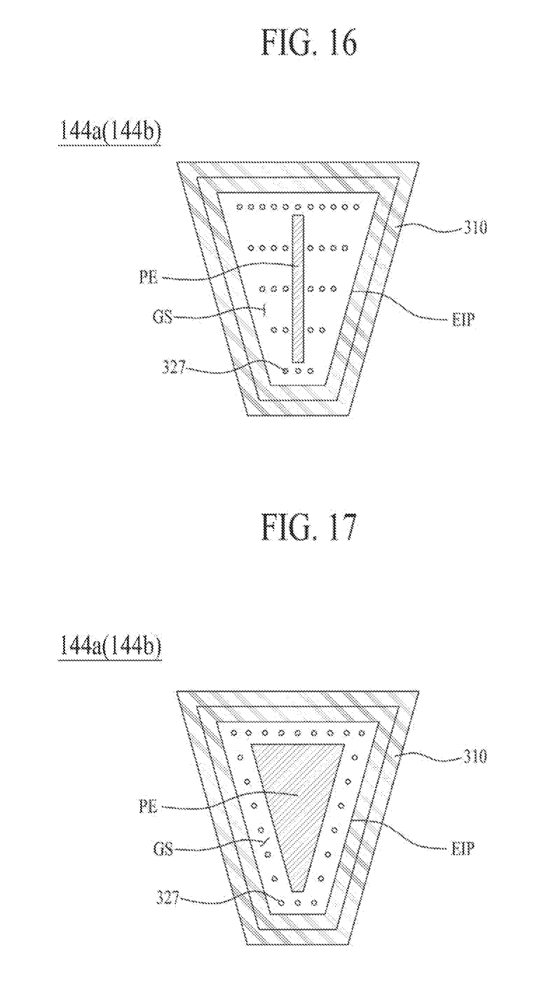

FIGS. 16 to 18 are rear views illustrating the first gas distributing module shown in FIGS. 3 to 5, which illustrate various shapes of the protruding electrode and the electrode inserting portion shown in FIGS. 3 to 5. Accordingly, only the various shapes of the protruding electrode and the electrode inserting portion will be described in detail as follows.

First, the first gas distributing module 144a shown in FIGS. 3 to 5 may have the same structure as that shown in any one of FIGS. 9 to 11, and the housing 210 may have a trapezoid shape on the plane.

If the first gas distributing module 144a according to another modified embodiment of the present invention has the same structure as that shown in FIG. 11, the first gas distributing module 144a may include one electrode inserting portion (EIP) and one protruding electrode (PE), as shown in FIG. 16.

The electrode inserting portion (EIP) may have the trapezoid shape on the plane.

The protruding electrode (PE) is formed in a rectangular pillar which is provided at a predetermined interval from the lateral surface of the electrode inserting portion (EIP) and is also surrounded by the lateral surface of the electrode inserting portion (EIP). In FIG. 16, one protruding electrode (PE) is inserted into and positioned in the electrode inserting portion (EIP), but not limited to this structure. For example, the plurality of protruding electrodes (PE) arranged in parallel at fixed intervals may be inserted into the electrode inserting portion (EIP).

The aforementioned gap space (GS) is prepared between the lateral surface of the electrode inserting portion (EIP) and the protruding electrode (PE), and the first gas is distributed from the plurality of gas distributing holes 327 of the second electrode frame 320 to the gap space (GS). In this case, the plurality of gas distributing holes 327 are provided in such a manner that their numbers are gradually increased from one lateral side to the other lateral side of the first gas distributing module 144a. Also, a gas distributing amount is gradually increased from one lateral side to the other lateral side of the first gas distributing module 144a.

As shown in FIG. 17, one protruding electrode (PE) is formed in a pillar type having a trapezoid planar shape, whereby the protruding electrode (PE) is surrounded by the internal lateral surface of the trapezoid-shaped electrode inserting portion (EIP). In this case, the lateral surface of one protruding electrode (PE) is provided at a predetermined interval from the internal lateral surface of the electrode inserting portion (EIP), whereby the gap space (GS) with the predetermined interval is prepared between the lateral surface of one protruding electrode (PE) and the internal lateral surface of the electrode inserting portion (EIP).

Meanwhile, the lower surface of the protruding electrode (PE) shown in FIGS. 16 and 17 may be gradually inclined from the inner side of the first electrode frame 310 being adjacent to the center of the substrate supporter 120 toward the outer side of the first electrode frame 310. For example, one side of the lower surface of the protruding electrode (PE) being adjacent to the inner side of the first electrode frame 310 is positioned at the same line as the lower surface of the first electrode frame 310, and the other side of the lower surface of the protruding electrode (PE) being adjacent to the outer side of the first electrode frame 310 is positioned inside the first electrode frame 310, whereby the lower surface of the protruding electrode (PE) is inclined at a predetermined angle with respect to the lower surface of the first electrode frame 310.

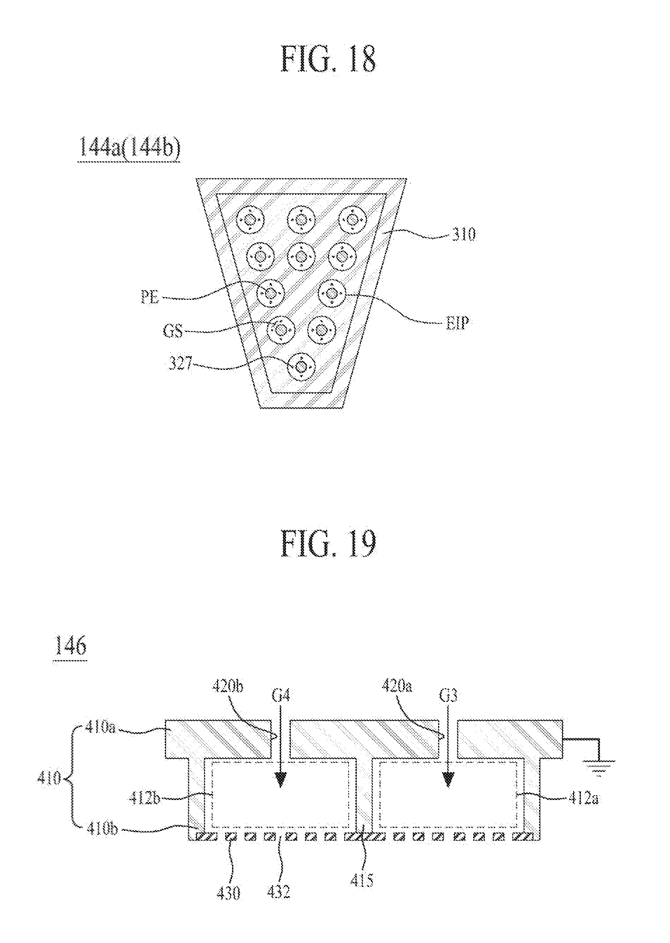

If the first gas distributing module 144a according to another modified embodiment of the present invention has the same structure as that shown in FIG. 11, the first gas distributing module 144a may include the plurality of electrode inserting portions (EIP) and the plurality of protruding electrodes (PE), as shown in FIG. 18.

The electrode inserting portion (EIP) is formed in a circular shape on the plane, and is arranged in a trapezoid shape on the plane. The protruding electrode (PE) is formed in a circular pillar which is provided at a predetermined interval from the lateral surface of the electrode inserting portion (EIP) and is also surrounded by the lateral surface of the electrode inserting portion (EIP). The aforementioned gap space (GS) is prepared between the lateral surface of the electrode inserting portion (EIP) and the protruding electrode (PE), and the first gas is distributed from the plurality of gas distributing holes 327 of the second electrode frame 320 to the gap space (GS).

The electrode inserting portion (EIP) shown in FIG. 18 is not limited to the circular shape on the plane. As shown in FIGS. 14 and 15, the electrode inserting portion (EIP) may be formed in a polygonal cross section whose internal angle is above 90°. Also, the protruding electrode (PE) is not limited to the circular pillar surrounded by the electrode inserting portion (EIP). For example, the protruding electrode (PE) may be formed in a pillar shape which is the same as that of the electrode inserting portion (EIP), or may be formed in a pillar shape having a polygonal cross section whose internal angle is above 90°.

Meanwhile, the second gas distributing module 144b shown in FIG. 1 is the same in structure as the aforementioned first gas distributing module 144a described with reference to FIGS. 9 to 18, except that the second gas supplied from the external second gas supplier is distributed to the second gas reaction region of the first reaction space, whereby a detailed description for the second gas distributing module 144b will be omitted.

FIG. 19 illustrates the first embodiment of the second gas distributing means shown in FIG. 1.

Referring to FIG. 19 in connection with FIG. 1, the second gas distributing means 146 according to the first embodiment of the present invention may include a housing 410 with a plate 410a and a sidewall 410b; a partition member 415 for spatially separating the inside of the housing 410 into third and fourth gas distributing spaces 412a and 412b; at least one of third gas supply hole 420a for supplying third gas (G3) to the third gas distributing space 412a, wherein the third gas supply hole 420a is formed at one side of the plate 410a; at least one of fourth gas supply hole 420b for supplying fourth gas (G4) to the fourth gas distributing space 412b, wherein the fourth gas supply hole 420b is formed at the other side of the plate 410a; and a gas distributing pattern member 430 combined with a lower surface of the housing 410 so as to cover a lower surface of each of the third and fourth gas distributing spaces 412a and 412b, wherein the gas distributing pattern member 430 distributes the gas through a gas distributing pattern 432.

In case of the second gas distributing means 146 having the above structure, the inner space of the housing 410 is spatially separated into the third and fourth gas distributing spaces 412a and 412b, and the different kinds of gases (G3, G4) are respectively supplied to the third and fourth gas distributing spaces 412a and 412b. Except that, the second gas distributing means 146 of FIG. 19 is the same in structure as the first or second gas distributing module 144a or 144b shown in FIG. 9, whereby a detailed description for the second gas distributing means 146 will be omitted.

The second gas distributing means 146 distributes the third gas (G3) to the aforementioned second reaction space 114 through the third gas distributing space 412a, and simultaneously distributes the fourth gas (G4) to the aforementioned second reaction space 114 through the fourth gas distributing space 412b. According as each substrate 10 passes through the second reaction space 114 by the rotation of the aforementioned substrate supporter 120, a thin film is deposited on the substrate 10 by the chemical vapor reaction of the third and fourth gases, or a dopant is doped on the substrate 10 by the chemical vapor reaction of the third and fourth gases.

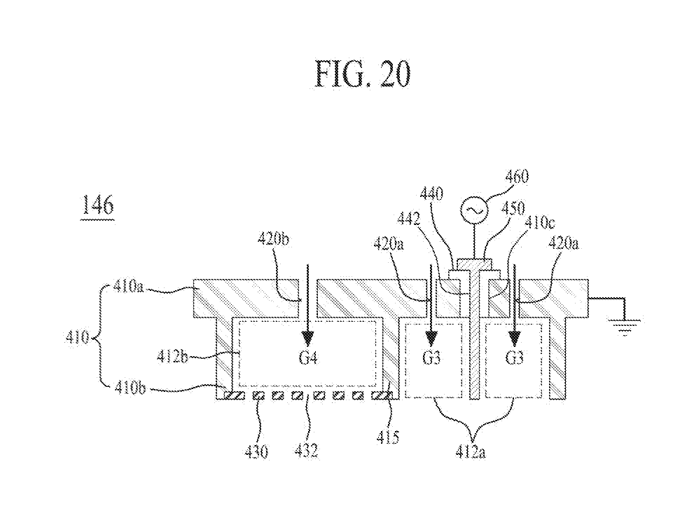

FIG. 20 illustrates the second embodiment of the second gas distributing means shown in FIG. 1, which shows an additionally-provided plasma electrode 450 in the third gas distributing space 412a of FIG. 19. Hereinafter, only the different structure will be described in detail as follows.

First, in case of the second gas distributing means 146 shown in FIG. 19, third gas (G3) is not activated and is then distributed onto the substrate. However, it is needed to activate the third gas (G3) and to distribute the activated third gas onto the substrate in accordance with the kind of thin film to be deposited onto the substrate. Accordingly, the second gas distributing means 146 according to the second embodiment of the present invention activates the third gas (G3), and then distributes the activated third gas onto the substrate.

The second gas distributing means 146 according to the second embodiment of the present invention may further include the plasma electrode 450 which is inserted into and arranged in the third gas distributing space 412a. In this case, an insulating member insertion hole 410c being in communication with the third gas distributing space 412a is formed in the aforementioned plate 410a of the housing 410, and an insulating member 440 is inserted into the insulating member insertion hole 410c. Also, an electrode insertion hole 442 being in communication with the third gas distributing space 412a is formed in the insulating member 440, and the plasma electrode 450 is inserted into the electrode insertion hole 442.

The plasma electrode 450 is inserted into the third gas distributing space 412a, and is arranged in parallel to the sidewall 410b and the partition member 415 or surrounded by the sidewall 410b and the partition member 415. In this case, a lower surface of the plasma electrode 450 may be positioned at the same height as a that of the sidewall 410b, or may be protruding out of the lower surface of the sidewall 410b or not.

The plasma electrode 450 forms the plasma from the third gas (G3) supplied to the third gas distributing space 412a in accordance with plasma power supplied from a plasma power supplier 460. In this case, the plasma is formed by an electric field among the plasma electrode 450, the sidewall 410b and the partition member 415 in accordance with the plasma power. Accordingly, the third gas (G3) supplied to the third gas distributing space 412a is activated by the plasma, and then the activated third gas (G3) is distributed to the second reaction space 114.

An interval (or gap) between the plasma electrode 450 and the sidewall 410b is smaller than an interval between the plasma electrode 450 and the substrate. Instead of forming the plasma between the substrate and the plasma electrode 450, the plasma is formed among the plasma electrode 450, the sidewall 410b and the partition member 415 arranged in parallel so that it is possible to prevent the substrate and/or thin film from being damaged by the plasma.

In FIG. 20, the plasma electrode 450 is arranged in the third gas distributing space 412a, but not limited to this structure. The plasma electrode 450 is also arranged in the fourth gas distributing space 412b, to thereby form the plasma in the fourth gas distributing space 412b. In this case, the fourth gas (G4) supplied to the fourth gas distributing space 412b is activated by the plasma, and then the activated fourth gas (G4) is distributed to the second reaction space 114.

Meanwhile, the second gas distributing means 146 according to the third embodiment of the present invention may be the same in structure to the first and second gas distributing modules 144a and 144b shown in FIG. 11. In this case, a mixture gas of the third and fourth gases (G3, G4) is supplied to the aforementioned gas supply flow path 323 of the second electrode frame 320, and the mixture gas is distributed to the gap space (GS) through the plurality of gas distributing flow paths 325 and the plurality of gas distributing holes 327, whereby the mixture gas is activated by the plasma occurring in the gap space (GS) in accordance with the potential difference between the first electrode frame 310 and the protruding electrode (PE), and is then distributed to the second reaction space 114.

The substrate processing apparatus according to the present invention, the process space of the process chamber may be separated into the first and second reaction spaces by the use of purge gas, and the single-layered or multi-layered thin film may be deposited in each of the first and second reaction spaces through the different deposition reactions, to thereby improve uniformity of the thin film deposited on the substrate, and also to adjust productivity with easiness. Especially, the substrate processing apparatus according to the present invention enables to adjust the ratio of the atomic layer adsorption reaction in the first reaction space and the ratio of the chemical vapor reaction in the second reaction space so that it is possible to facilitate improving the quality of thin film and adjusting the productivity.

Furthermore, the substrate processing apparatus according to the present invention enables to deposit the thin film by any one process of the atomic layer adsorption reaction in the first reaction space and the chemical vapor reaction in the second reaction space, and also to dope the thin film with the dopant by the remaining reaction, to thereby perform the various processes for processing the substrate in one process chamber.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A substrate processing apparatus comprising:
a process chamber for providing a process space;
a substrate supporter, which is rotatably provided in the process space, for supporting at least one substrate;
a chamber lid confronting the substrate supporter, the chamber lid for covering an upper side of the process chamber; and
a gas distributing part for spatially separating the process space into first and second reaction spaces, and inducing the different kinds of deposition reactions in the respective first and second reaction spaces, wherein the gas distributing part is provided in the chamber lid.

2. The substrate processing apparatus according to claim 1, wherein a thin film is deposited on the substrate by an atomic layer adsorption reaction in the first reaction space, and a thin film is deposited on the substrate by a chemical vapor reaction in the second reaction space.

3. The substrate processing apparatus according to claim 1, wherein the substrate passes through the first and second reaction spaces by a rotation of the substrate supporter, and a thin film is deposited on the substrate in accordance with a deposition reaction of gas distributed from the gas distributing part to at least any one of the first and second reaction spaces.

4. The substrate processing apparatus according to claim 2, wherein the gas distributing part includes:
a space separating means for spatially separating the process space of the process chamber into the first and second reaction spaces;
a first gas distributing means for distributing process gas of the chemical vapor reaction to the first reaction space; and
a second gas distributing means for distributing process gas of the atomic layer adsorption reaction to the second reaction space.

5. The substrate processing apparatus according to claim 4, wherein the space separating means forms a gas barrier by distributing purge gas to a space between the first and second reaction spaces.

6. The substrate processing apparatus according to claim 4, wherein the space separating means forms a gas barrier by distributing purge gas to a space between the first and second reaction spaces, and separates the first reaction space into at least one first gas reaction region and at least one second gas reaction region by locally distributing purge gas to the first reaction space.

7. The substrate processing apparatus according to claim 6, wherein the first gas distributing means includes:
at least one first gas distributing module for distributing first gas to the at least one first gas reaction region; and
at least one second gas distributing module for distributing second gas to the at least one second gas reaction region, wherein the second gas is different from the first gas.

8. The substrate processing apparatus according to claim 7, wherein the first gas corresponds to source gas including a material for the thin film, and the second gas corresponds to reaction gas which reacts on the first gas.

9. The substrate processing apparatus according to claim 8, wherein at least any one of the first and second gas distributing modules activates corresponding gas distributed to a space between the first and second electrodes by the use of plasma occurring due to a potential difference between the first electrode and the second electrode surrounded by the first electrode, and then distributes the activated corresponding gas.

10. The substrate processing apparatus according to claim 9, wherein each of the first and second electrodes has a circular or polygonal shaped cross section.

11. The substrate processing apparatus according to claim 7, wherein each of the first and second gas distributing modules has one side being adjacent to the center of the substrate supporter and the other side being adjacent to the edge of the substrate supporter, and a length of one side therein is the same as or different from the other side therein.

12. The substrate processing apparatus according to claim 1, wherein the second gas distributing means distributes fourth gas together with third gas to the second reaction space.

13. The substrate processing apparatus according to claim 12, wherein the third gas corresponds to source gas including a material for the thin film, and the fourth gas corresponds to reaction gas which reacts on the third gas.

14. The substrate processing apparatus according to claim 12, wherein the second gas distributing means activates at least any one of the third and fourth gases by the use of plasma occurring owing to a plasma electrode and a ground electrode surrounding the plasma electrode, and then distributes the activated gas.

15. The substrate processing apparatus according to claim 14, wherein the second gas distributing means includes one side being adjacent to the center of the substrate supporter and the other side being adjacent to the edge of the substrate supporter, and a length of one side therein is the same as or different from the other side therein.
